(19) United States
(12) Patent Application Publication
(10) Pub. No.: US 2016/0018440 A1
(43) Pub. Date: Jan. 21, 2016

(54) Contact Device for Test and Test Socket

(71) Applicant: ISC Co., Ltd., Seongnam-si (KR)

(72) Inventor: Young Bae CHUNG, Seongnam-si (KR)

(21) Appl. No.: 14/794,009

(22) Filed: Jul. 8, 2015

(30) Foreign Application Priority Data
Jul. 17, 2014 (KR) 10-2014-0090347

(51) Int. Cl. G01R 1/067; G01R 1/04

(52) U.S. Cl. CPC G01R 1/06722; G01R 1/0408

(57) ABSTRACT

Provided are a contact device for tests and an electric test socket. The contact device is used to electrically connect a terminal of a test target device to a pad of an inspection apparatus. The contact device includes a first plate member, second plate members, and a spring supporting the first and second plate members in a relatively slidable manner.

### CROSS-REFERENCE TO RELATED APPLICATION

This application claims the benefit of Korean Patent Application No. 10-2014-0090347, filed on Jul. 17, 2014, in the Korean Intellectual Property Office, the disclosure of which is incorporated herein in its entirety by reference.

### BACKGROUND

1. Field

One or more exemplary embodiments relate to a contact device for tests and an electric test socket, and more particularly to, a contact device for tests which is configured to be minimally worn by an inner wall of a housing and thus to have a long life span, and an electric test socket.

2. Description of the Related Art

In general, stable electric connection between a device and an inspection apparatus is necessary when electric characteristics of the device are inspected. To this end, an electrical test socket is generally used to connect an inspection apparatus to a device to be inspected.

The function of such electric test sockets is to connect terminals of a device to pads of an inspection apparatus to allow two-way transmission of electric signals between the device and the inspection apparatus. Examples of electric test sockets include conductive rubber type sockets using a conductive rubber part as a contact and pogo pin type sockets using a metal pin and a spring as a contact unit. An elastic conductive part of such a conductive rubber type socket is connected to a terminal of a device to be inspected. A metal pin of such a pogo pin type socket is connected to a terminal of a device to be inspected, and a spring absorbs mechanical impacts when the device is connected to the pogo pin type socket.

Among such electric test sockets of the related art, pogo pin type sockets which are constituted by a metal pin and a spring that are disposed in a cylinder are relatively expensive. Thus, sockets using an in expensive plate-type metal pin as shown in FIGS. 1 to 5 have been developed.

An example of electric test sockets using such inexpensive plate-type metal pins is illustrated in FIGS. 1 and 2. Referring to FIGS. 1 and 2, the exemplary electric socket includes two identical contact pins 2 and a coil spring 3. Each of the contact pins 2 includes hooking protrusions 4, a hook hole 5, flanges 6, and pin tips 2A. The hooking protrusions 4 are two in number and face each other, and support bars 4A support the hooking protrusions 4. The two hooking protrusions 4 are located close to each other but are separate from each other. The hook hole 5 is formed for coupling with the hooking protrusions 4. To this end, the hook hole 5 has a rectangular shape corresponding to the widths of the hooking protrusions 4. Therefore, if the two contact pins 2 are coupled together in mutually-facing directions at a twist angle of 90° therebetween, the two pairs of hooking protrusions 4 are hooked on each other and thus are not separated from each other. The flanges 6 make contact with the coil spring 3. Since the two contact pins 2 are coupled to each other in the coil spring 3 at a twist angle of 90°, both ends of the coil spring 3 are in contact with the flanges 6. In this manner, a contact unit 1 is formed in a stacked manner. The pin tips 2A are formed on both ends of the contact unit 1 in which the two contact pins 2 are coupled together in a stacked manner, and parts such as electrodes may be brought into contact with the pin tips 2A for making an electric connection.

In addition, an exemplary electric test socket of the related art is disclosed in Korean Patent No. 10-1310672 as illustrated in FIGS. 3 to 5. In detail, the disclosed electric test socket mainly includes a circuit board 15, a lower housing 16, an upper housing 17, a frame (not shown), a guide plate 19, and contact units 20.

Each of the contact units 20 includes: a first plunger having a plate shape and making contact with a member; second plungers 63 having a plate shape, the second plungers 63 overlapping the first plunger and making contact with another member with a large contact area so that the members may be electrically connected by the first plunger and the second plungers 63; a compression coil spring 64 combining the first plunger and the second plungers 63 in a state in which contact sections (regions for contact) of the first plunger and the second plungers 63 face in opposite directions, the compression coil spring 64 surrounding coupling portions of the first plunger and the second plungers 63 and making contact with spring support portions of the first plunger and the second plungers 63 so as to allow the first plunger and the second plungers 63 to slide relative to each other.

The first plunger is single, and the second plungers 63 are two in number (the opposite case is also possible). The coupling portion of the first plunger having a plate shape is disposed between the coupling portions of the second plungers 63 having a plate shape. The coupling portion of the first plunger is wider than the coupling portions of the second plungers 63, and the inner diameter of both ends of the compression coil spring 64 is equal to or smaller than the diameter of the circumcircle of a cross section of the coupling portions of the first plunger and the second plungers 63 overlapping each other.

However, in such an electric test socket as that shown in FIGS. 1 to 5, a plate-shaped plunger is in frictional contact with the inner wall of a penetration hole of a housing, thereby causing abrasion of the housing. That is, since a plate-shaped plunger having a rectangular cross section is disposed in a circular penetration hole of a housing, while the plate-shaped plunger vertically slides, sharp edges of the plate-shaped plunger may contact and damage the inner wall of the penetration hole of the housing.

To address this, a penetration hole having a rectangular cross-sectional shape may be formed in a housing. However, it costs more to form a rectangular hole in a housing than to form a circular hole in a housing, thereby increasing manufacturing costs.

Furthermore, if a rectangular hole is formed in a housing for an inexpensive plate-shaped plunger, the housing may not be used together with existing pogo pins.

### RELATED ART DOCUMENT

(Patent Document 1) Korean Patent No.: 10-1310672

### SUMMARY

One or more exemplary embodiments include a contact device for tests which does not excessively wear down or damage a housing when the contact device vertically slide in a penetration hole of the housing, and an electric test socket.

Additional aspects will be set forth in part in the description which follows and, in part, will be apparent from the description, or may be learned by practice of the presented embodiments.

According to one or more exemplary embodiments, there is provided a contact device for tests, the contact device being configured to be inserted into one of circular penetration holes of a housing formed at positions corresponding to terminals of a test target device for electrically connecting a terminal of the test target device to a pad of an inspection apparatus, the contact device including:

a first plate member including a first probe portion and a first contact portion extending upward from the first probe portion, wherein a probe is formed on a lower end of the first probe portion;

a pair of second plate members separate from each other with the first plate member being disposed therebetween, each of the second plate members including a second probe portion and a second contact portion extending downward from the second probe portion and making surface contact with the first contact portion, wherein a probe is formed on an upper end of the second probe portion, and the second probe portion has a predetermined width and extends downward; and

a spring surrounding overlapping regions of the first and second contact portions and supporting the first and second plate members in a relatively slidable manner,

wherein a second protruding portion is formed on a side of the second probe portion facing an inner wall of the penetration hole, so as to fill at least a portion of a gap between the inner wall of the penetration hole and the side of the second probe portion, and

a horizontal cross section of the second protruding portion has a dome shape formed by rounding corners of a rectangular shape, and the rounded corners are in contact with the inner wall of the penetration hole such that the second protruding portion is in contact with the inner wall of the penetration hole at at least two positions.

A width of the second protruding portion may be narrower than a width of the second probe portion.

Corners of the second probe portion may be rounded.

The second probe portion may be brought into contact with the terminal of the test target device.

According to one or more exemplary embodiments, an electric test socket includes: the contact device; and a housing including penetration holes at positions corresponding to terminals of a test target device, wherein the penetration holes has a circular cross section.

As described above, according to exemplary embodiments, since the second plate members of the contact device have a shape corresponding to the circular penetration holes of the housing, when the contact device is vertically slid in a penetration hole of the housing, the contact device may minimally wear down the housing.

### BRIEF DESCRIPTION OF THE DRAWINGS

These and/or other aspects will become apparent and more readily appreciated from the following description of the embodiments, taken in conjunction with the accompanying drawings in which:

FIGS. 1 and 2 are views illustrating an exemplary plate-shaped test device of the related art;

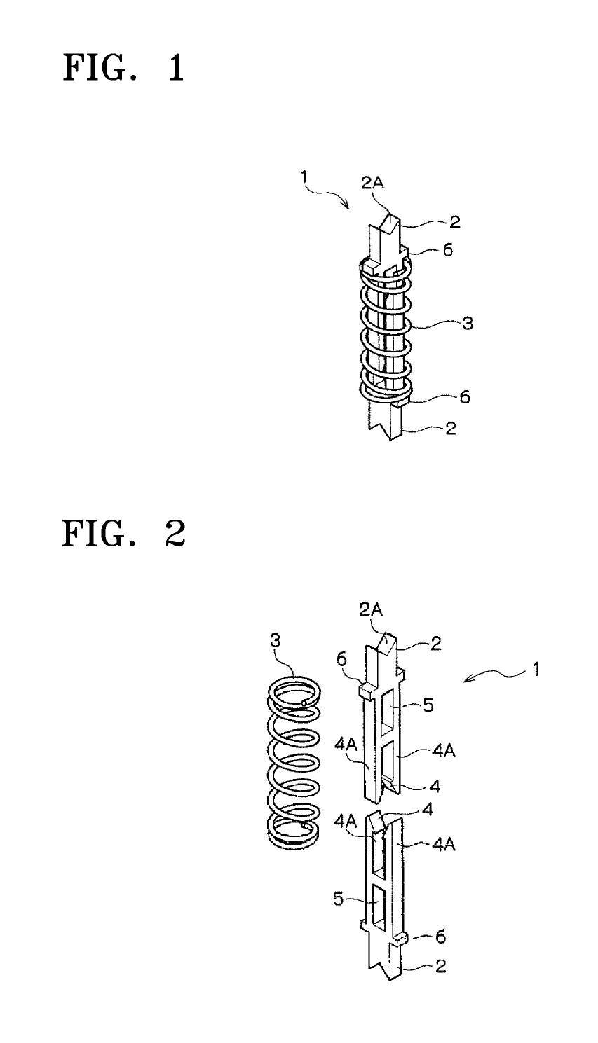

FIGS. 3 and 5 are views illustrating another exemplary plate-shaped test device of the related art;

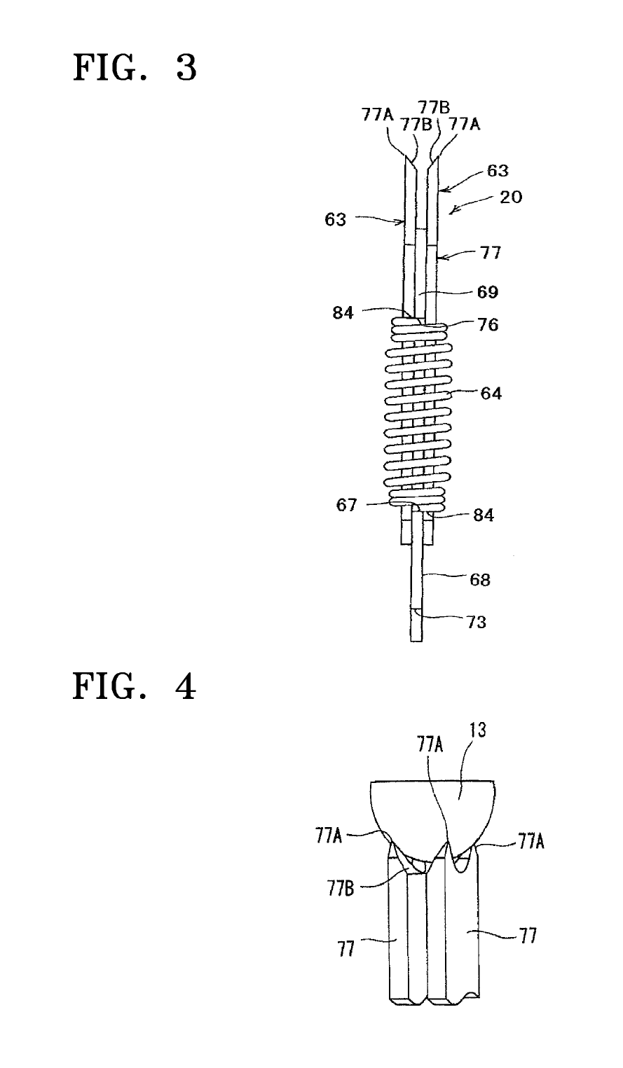

FIG. 6 is a perspective view illustrating a plate-shaped contact device for tests according to an exemplary embodiment;

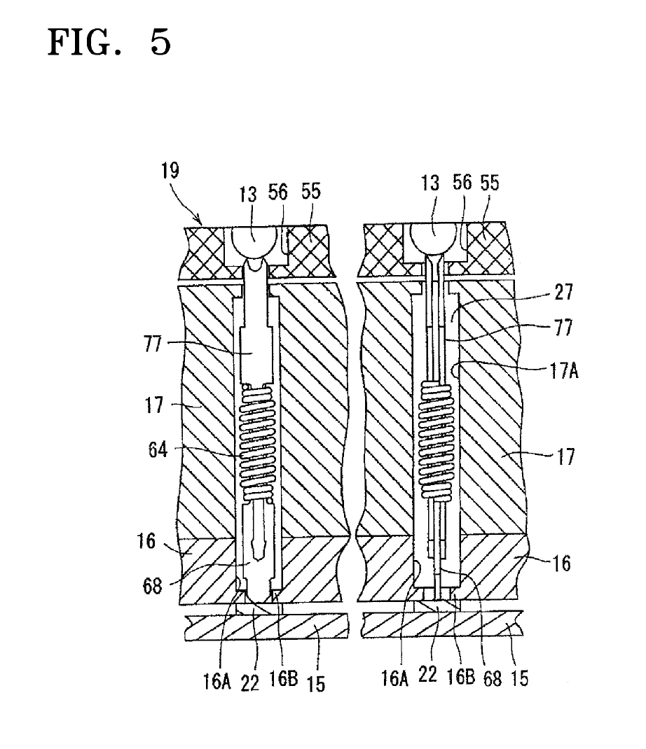

FIG. 7 is a cross-sectional view taken along a line VII-VII of FIG. 6;

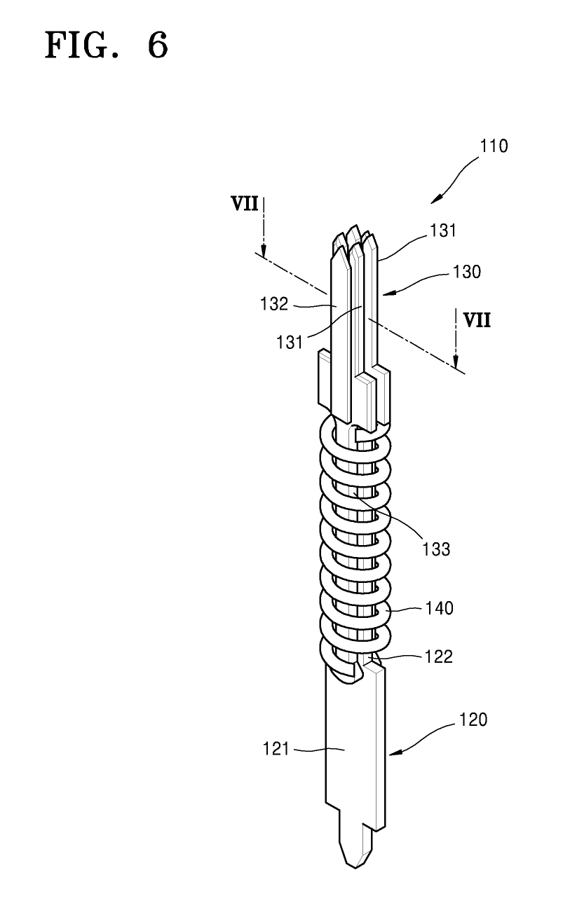

FIG. 8 is an enlarged view illustrating a plate-shaped contact device for tests according to another exemplary embodiment; and

FIG. 9 is a cross-sectional view illustrating a plate-shaped contact device for tests according to another exemplary embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, a contact device for tests will be described in detail according to exemplary embodiments with reference to the accompanying drawings.

According to an exemplary embodiment, a contact device 110 for tests is used to electrically connect a terminal of a test target device (not shown) to a pad of an inspection apparatus (not shown). To this end, the contact device 110 may be inserted into a penetration hole (not shown) formed in a housing (not shown) at a position corresponding to a terminal of a test target device. The term “test target device” may refer to a semiconductor device such as a device having integrated circuits. For example, the term “test target device” may refer to a semiconductor device having a plurality of ball-shaped terminals arranged on a lower surface thereof. However, the term “test target device” is not limited thereto. For example, the term “test target device” may refer to any kind of semiconductor device.

The contact device 110 includes a first plate member 120, a pair of second plate members 130, and a spring 140.

The first plate member 120 includes: a first probe portion 121 having a probe on an end thereof; and a first contact portion 122 extending upward from the first probe portion 121. An end of the first plate member 120 may be brought into contact with a pad of an inspection apparatus. However, the embodiments of the present disclosure are not limited thereto. For example, the first plate member 120 may be brought into contact with a terminal of a test target device. The first plate member 120 is disposed between the pair of second plate members 130.

The first plate member 120 may be formed of a conductive material through a grinding process, a pressing process, or a process using microelectromechanical system (MEMS) and photolithography. For example, the first plate member 120 may be formed of a nickel alloy or any other material having a high degree of conductivity.

The first probe portion 121 includes: a pointed tongue on an end thereof; a region having a predetermined width (greater than the inner diameter of the spring 140) extending upward from the tongue; and a jaw formed on an upper end to support the spring 140.

The first contact portion 122 extends upward from the first probe portion 121. The first contact portion 122 is disposed between the second plate members 130 in contact with the second plate members 130. That is, both sides of the first contact portion 122 are in contact with sides of the second plate members 130 so that the first contact portion 122 may be electrically connected to the second plate members 130. The spring 140 is disposed around the first contact portion 122. To this end, the width of the first contact portion 122 may be smaller than the inner diameter of the spring 140.

The second plate members 130 are provided as a pair and separate from each other with the first plate member 120 being disposed therebetween. Each of the second plate members 130 includes: a second probe portion 131 having probes on an end thereof, the second probe portion 131 having a predetermined width and extending downward; and a second contact portion 133 extending downward from the second probe portion 131 and making surface contact with the first contact portion 122.

Like the first plate member 120, the second plate members 130 may be formed of a conductive material through a grinding process, a pressing process, or a process using a MEMS and photolithography. For example, the second plate members 130 may be formed of a nickel alloy or any other material having a high degree of conductivity.

The second probe portion 131 of each of the second plate members 130 includes: a plurality of pointed parts formed on an upper end thereof; and a body having a predetermined width (greater than the inner diameter of the spring 140) and extending downward from the pointed parts.

Second protruding portions 132 are provided on sides of the second probe portions 131 facing an inner wall of the penetration hole of the housing so as to fill at least portions of gaps between the inner wall of the penetration hole of the housing and the sides of the second probe portions 131. The widths of the second protruding portions 132 are narrower than the widths of the second probe portions 131. Horizontal cross sections of the second protruding portions 132 may have a semicircular shape, or a dome shape formed by rounding corners of a rectangular shape. A pointed tongue may extend upward from an upper end of each of the second protruding portions 132 for making contact with a terminal of a test target device.

In addition, the second protruding portions 132 and the second probe portions 131 may be located inside an imaginary circle, and at least a portion of the second protruding portions 132 or the second probe portions 131 may touch the imaginary circle. That is, when the second protruding portions 132 and the second probe portions 131 are disposed inside the housing, the second protruding portions 132 and the second protruding portions 132 may be in contact with the housing with a large contact area therebetween or at as many positions as possible. In detail, rounded corners of the second protruding portions 132 are in contact with the inner wall of the penetration hole of the housing such that at least two positions (the rounded corners) of each of the second protruding portions 132 may be in contact with the inner wall of the penetration hole of the housing. In addition, corners of the second probe portions 131 may be in contact with the inner wall of the penetration hole of the housing. In this manner, since the second protruding portions 132 and the second probe portions 131 make surface contact with the inner wall of the housing or make contact with many positions of the inner wall of the housing, a force applied to the housing may be optimally distributed. That is, a force may not be locally applied to the housing. Like the second protruding portions 132, corners of the second probe portions 131 may be rounded.

The second contact portions 133 extend downward from the second probe portions 131 and make contact with sides of the first contact portion 122 for electric connection with the first contact portion 122. The second contact portions 133 are inserted into the spring 140. To this end, the widths of the second contact portions 133 may be smaller than the inner diameter of the spring 140.

The spring 140 surrounds overlapping regions of the first contact portion 122 and the second contact portions 133 so that the first plate member 120 and the second plate members 130 may be supported in a relatively slidable manner. In a state in which upper and lower ends of the spring 140 are supported by the second probe portions 131 and the first probe portion 121, the spring 140 surrounds the first and second contact portions 122 and 133 so that the first probe portion 121 and the second probe portions 131 may be elastically biased in receding directions.

The contact device 110 of the exemplary embodiment may have the following operational effects.

First, the contact device 110 is disposed on an inspection apparatus, and a test target device is moved to the contact device 110 to bring a terminal of the test target device into contact with the contact device 110.

In detail, the test target device is moved to bring the terminal of the test target device into contact with the pair of second plate members 130. When the test target device is moved and the second plate members 130 are brought into contact with the terminal of the test target device, the second plate members 130 is slid downward, and the spring 140 elastically supports the second plate members 130. When the second plate members 130 are slid as described above, the second plate members 130 are in contact with the inner wall of the penetration hole of the housing at as many portions as possible, and thus the inner wall of the penetration hole of the housing may be less scratched or damaged.

For example, even if the penetration hole of the housing has a circular shape, since portions of the second plate members 130 making contact with the inner wall of the penetration hole of the housing are rounded, the housing may be minimally damaged.

As described above, according to the exemplary embodiment, even if the penetration hole of the housing has a circular shape, the inner wall of the penetration hole of the housing may be minimally worn by the first and second plate members 120 and 130.

An exemplary embodiment may provide an electric test socket 100 including the contact device 110 and a housing in which penetration holes are formed at positions corresponding terminals of a test target device.

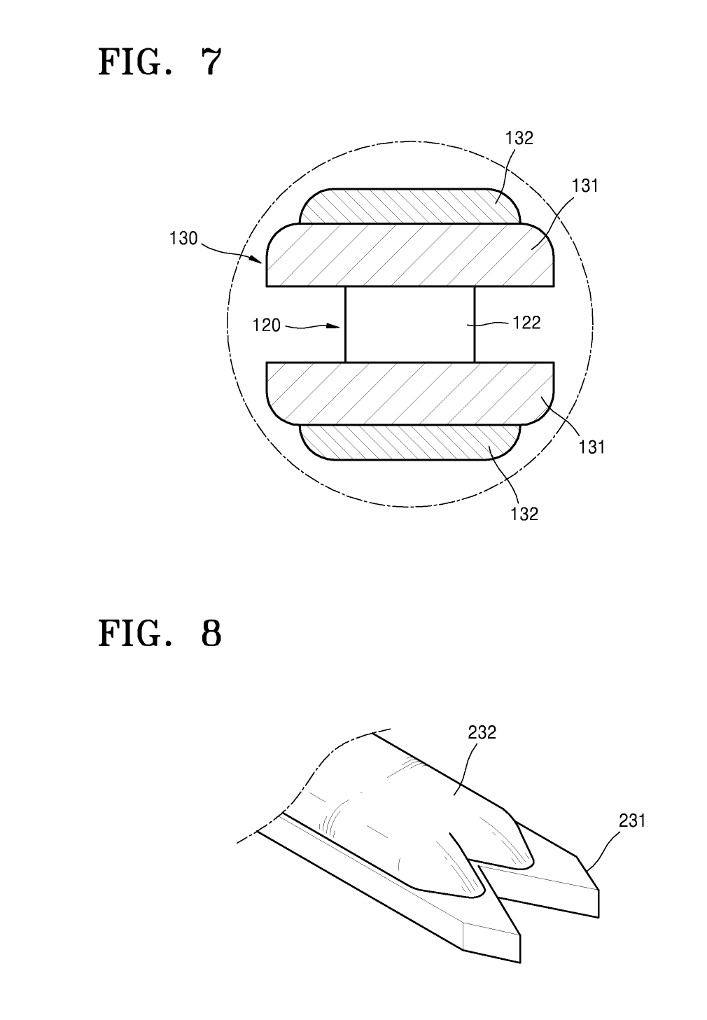

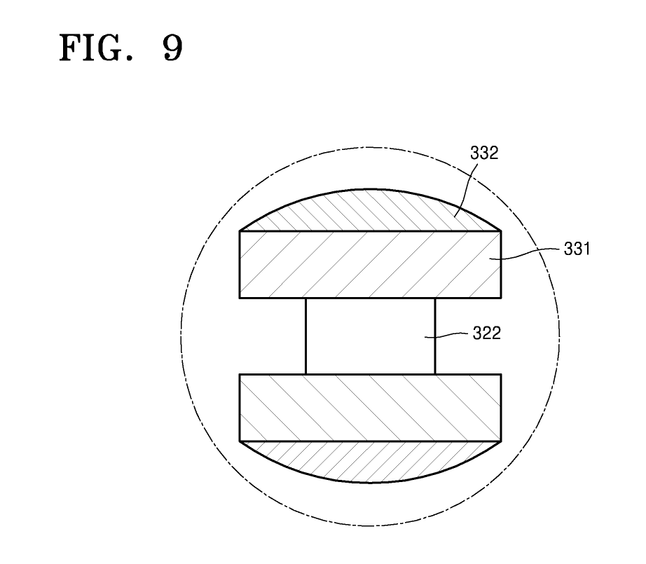

The contact device 110 is an example. That is, the embodiments of the present disclosure are not limited to the contact device 110. For example, the contact device 110 may be modified as shown in FIGS. 8 and 9.

In the above-described exemplary embodiment, the upper end of each of the second protruding portion 132 has a single pointed tongue. However, the embodiments of the present disclosure are not limited thereto. For example, as shown in FIG. 8, a plurality of pointed tongues may be formed on an upper end of a second protruding portion 232, and the second protruding portion 232 may be placed on a side of a second probe portion 231.

In addition, as shown in FIG. 9, a second protruding portion 332 having an elliptical shape may be formed on a side of a second probe portion 331 and may protrude from both lateral edges of a second probe portion 331.

In the above-described exemplary embodiments, the second protruding portions 132, 232, or 332 are formed on the second probe portions 131, 231, or 331. However, the embodiments of the present disclosure are not limited thereto. For example, a first protruding portion may be formed on the first probe portion 121.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope of the inventive concept as defined by the following claims.

What is claimed is:

1. A contact device for tests, the contact device being configured to be inserted into one of circular penetration holes of a housing formed at positions corresponding to terminals of a test target device for electrically connecting a terminal of the test target device to a pad of an inspection apparatus, the contact device comprising:
a first plate member comprising a first probe portion and a first contact portion extending upward from the first probe portion, wherein a probe is formed on a lower end of the first probe portion;
a pair of second plate members separate from each other with the first plate member being disposed therebetween, each of the second plate members comprising a second probe portion and a second contact portion extending downward from the second probe portion and making surface contact with the first contact portion, wherein a probe is formed on an upper end of the second probe portion, and the second probe portion has a predetermined width and extends downward; and
a spring surrounding overlapping regions of the first and second contact portions and supporting the first and second plate members in a relatively slidable manner,
wherein a second protruding portion is formed on a side of the second probe portion facing an inner wall of the penetration hole, so as to fill at least a portion of a gap between the inner wall of the penetration hole and the side of the second probe portion, and
a horizontal cross section of the second protruding portion has a dome shape formed by rounding corners of a rectangular shape, and the rounded corners are in contact with the inner wall of the penetration hole such that the second protruding portion is in contact with the inner wall of the penetration hole at at least two positions.

2. The contact device of claim 1, wherein a width of the second protruding portion is narrower than a width of the second probe portion.

3. The contact device of claim 1, wherein corners of the second probe portion are rounded.

4. The contact device of claim 1, wherein the second probe portion is brought into contact with the terminal of the test target device.

5. An electric test socket comprising:
the contact device of claim 1; and
a housing comprising penetration holes at positions corresponding to terminals of a test target device,
wherein the penetration holes has a circular cross section.
